(19) United States
(12) Patent Application Publication
(10) Pub. No.: US 2026/0277068 A1
(43) Pub. Date: Sep. 17, 2026

(54) ARRAY SUBSTRATE, FLEXIBLE COLOR ELECTRONIC PAPER DISPLAY PANEL, AND CONTROL METHOD

(71) Applicant: HKC CORPORATION LIMITED, Shenzhen (CN)

(72) Inventors: JUNHONG CAO, Shenzhen (CN); Lidan Ye, Shenzhen (CN)

(21) Appl. No.: 19/553,226

(22) Filed: Feb. 28, 2026

(30) Foreign Application Priority Data
Mar. 14, 2025 (CN) 202510302827.6

(51) Int. Cl. G02F 1/16766; G02F 1/167; G02F 1/1685; H10D 86/40

(52) U.S. Cl. CPC G02F 1/16766; G02F 1/167; G02F 1/1685; H10D 86/441

(57) ABSTRACT

An array substrate, a flexible color electronic paper display panel, and a control method are disclosed. Each pixel electrode includes a first and a second sub-pixel electrode. Each pixel element region includes a first and a second sub-pixel element region. The first sub-pixel electrode is disposed within the first sub-pixel element region. The second sub-pixel electrode is disposed within the second sub-pixel element region. The second sub-pixel electrode is disposed at a periphery of the first sub-pixel electrode. When the flexible color electronic paper display panel is in a bent state, each second sub-pixel electrode is used to control the electrophoretic reflective layer within the corresponding second sub-pixel element region to absorb light. When it is in an unbent state, each first sub-pixel electrode and the corresponding second sub-pixel electrode have an identical voltage, and the electric fields within the corresponding first and second sub-pixel element regions are identical.

### CROSS-REFERENCE TO RELATED APPLICATIONS

This application claims the priority and benefit of Chinese patent application number 2025103028276, titled “Array Substrate, Flexible Color Electronic Paper Display Panel, and Control Method” and filed Mar. 14, 2025 with China National Intellectual Property Administration, the entire contents of which are incorporated herein by reference.

### TECHNICAL FIELD

The present application relates to the field of display technology, and more particularly relates to an array substrate, a flexible color electronic paper display panel, and a control method.

### BACKGROUND

The description provided in this section is intended for the mere purpose of providing background information related to the present application but doesn't necessarily constitute prior art.

An electronic paper is an ultra-thin and ultra-light display device that closely resembles natural paper. It features high resolution and a wide viewing angle and is commonly used in electronic display devices. With the advancement of technology, the development of flexible color electronic paper display panels has made significant progress and is expected to find widespread applications in various fields in the future.

However, in related flexible color electronic paper display panels, when in a bent state, the misalignment between the upper and lower substrates can lead to color shift and color mixing issues in the displayed content.

### SUMMARY

In view of the above, it is therefore one objective of the present application to provide an array substrate, a flexible color electronic paper display panel, and a control method, which can prevent color shift and color mixing issues from occurring when the flexible color electronic paper display panel is in a bent state.

The present application discloses an array substrate for use in a flexible color electronic paper display panel. The flexible color electronic paper display panel includes an electrophoretic reflective layer. The array substrate includes an array base, and an active switching layer and a pixel electrode layer that are sequentially disposed on the array base. The array substrate further includes a plurality of pixel element regions.

The pixel electrode layer includes a plurality of pixel electrodes. The plurality of pixel electrodes are disposed in one-to-one correspondence with the plurality of pixel element regions. Each of the pixel electrodes includes a first sub-pixel electrode and a second sub-pixel electrode. Each of the pixel element regions includes a first sub-pixel element region and a second sub-pixel element region. The first sub-pixel electrode is located within the first sub-pixel element region. The second sub-pixel electrode is located within the second sub-pixel element region. The second sub-pixel electrode is disposed at a periphery of the first sub-pixel electrode.

When the flexible color electronic paper display panel is in a bent state, each of the second sub-pixel electrodes may be used to control an electrophoretic reflective layer within the corresponding second sub-pixel element region to absorb light. When the flexible color electronic paper display panel is in a non-bent state, the voltage of each first sub-pixel electrode is identical with that of the corresponding second sub-pixel electrode, and the electric fields within the corresponding first and second sub-pixel element regions are identical.

In some embodiments, the array substrate includes a display area and a non-display area, and the non-display area surrounds the display area. The plurality of pixel element regions are located within the display area. The display area includes a first region and a second region, which are respectively located on both sides of a center line.

In each pixel element region in the first region, the corresponding second sub-pixel electrode is located on the side of the corresponding first sub-pixel electrode facing towards the second region. In each pixel element region in the second region, the corresponding second sub-pixel electrode is located on the side of the corresponding first sub-pixel electrode facing towards the first region.

In some embodiments, the array substrate includes a display area and a non-display area, and the non-display area surrounds the display area. The plurality of pixel element regions are located within the display area. The display area includes a first region and a second region, which are respectively located on both sides of a center line.

In each pixel element region in the first region, the corresponding second sub-pixel electrode is located on the side of the corresponding first sub-pixel electrode that faces away from the second region. In each pixel element region in the second region, the corresponding second sub-pixel electrode is located on the side of the corresponding first sub-pixel electrode that faces away from the first region.

In some embodiments, the array substrate includes a display area and a non-display area, and the non-display area surrounds the display area. The plurality of pixel element regions are located within the display area. The display area includes a first region and a second region, which are respectively located on both sides of a center line.

Each pixel element region includes two second sub-pixel electrodes, and the two second sub-pixel electrodes within each pixel element region are electrically connected. In each pixel element region in the first region, the two corresponding second sub-pixel electrodes are respectively located on the sides of the corresponding first sub-pixel electrode that face toward and away from the second region. In each pixel element region in the second region, the two corresponding second sub-pixel electrodes are respectively located on the sides of the corresponding first sub-pixel electrode that face toward and away from the first region.

In some embodiments, the direction extending along the center line toward the first region is defined as a first direction, and the direction extending along the center line toward the second region is defined as a second direction.

In each pixel element region in the first region, along the first direction, the width of the second sub-pixel electrode gradually increases. In each pixel element region in the second region, along the second direction, the width of the second sub-pixel electrode gradually increases.

In some embodiments, the active switching layer includes a first active switch, a second active switch, a first data line, a second data line, and a scan line. The first active switch, the second active switch, the first data line, the second data line, and the scan line are all disposed on the array base. The first data line and the scan line are arranged in a grid pattern to define each pixel element region.

The first active switch connects the first data line and the first sub-pixel electrode. The second active switch connects the second data line and the second sub-pixel electrode. The scan line simultaneously controls both the first active switch and the second active switch to be turned on.

In some embodiments, the active switching layer includes a first active switch, a second active switch, a first data line, a second data line, a first scan line, and a second scan line. The first active switch, the second active switch, the first data line, the second data line, the first scan line, and the second scan line are all disposed on the array base. The first data line and the first scan line are arranged in a grid pattern to define each pixel element region.

The first active switch connects the first data line and the first sub-pixel electrode. The second active switch connects the second data line and the second sub-pixel electrode. The first scan line controls the first active switch to be turned on, and the second scan line controls the second active switch to be turned on.

The present application further discloses a flexible color electronic paper display panel, where the flexible color electronic paper display panel includes a color filter substrate, an electrophoretic reflective layer, and an array substrate. The electrophoretic reflective layer is disposed between the color filter substrate and the array substrate.

The present application further discloses a control method for a flexible color electronic paper display panel. The control method is applied to the flexible color electronic paper display panel, and the method includes:
detecting whether the flexible color electronic paper display panel is in a bent state;
when the flexible color electronic paper display panel is in the bent state, controlling the electrophoretic reflective layer corresponding to each second sub-pixel element region to absorb light; and
when the flexible color electronic paper display panel is not in the bent state, controlling the electric fields in each first sub-pixel element and the corresponding second sub-pixel element region to be identical.

In some embodiments, the operation of controlling the electrophoretic reflective layer corresponding to each second sub-pixel element region to absorb light when the flexible color electronic paper display panel is in a bent state further includes:
when the flexible color electronic paper display panel is in the bent state, applying a positive voltage to each second sub-pixel electrode to control the electrophoretic reflective layer within the corresponding second sub-pixel element region to absorb light.

Compared with the related solutions of flexible color electronic paper display panels, in the present application, each pixel electrode is divided into a first sub-pixel electrode and a second sub-pixel electrode, and the second sub-pixel electrode is disposed at a periphery of the first sub-pixel electrode. Thus, when the flexible color electronic paper display panel is in a bent state, although multiple color filters on the color filter substrate shift from the respective multiple pixel electrodes on the array substrate, each shifted color filter will fall onto the second sub-pixel electrode in an adjacent pixel element region. At this time, by controlling the electrophoretic reflective layer within the corresponding second sub-pixel element region to absorb light via the second sub-pixel electrode, color shift and mixing problems of the flexible color electronic paper display panel can be avoided. Furthermore, when the flexible color electronic paper display panel is in an unbent state, each first sub-pixel electrode and its corresponding second sub-pixel electrode have the same voltage, and the electric fields within the corresponding first and second sub-pixel element regions are identical, thereby preventing brightness reduction in the flexible color electronic paper display panel when it is not bent.

### BRIEF DESCRIPTION OF DRAWINGS

The accompanying drawings are used to provide a further understanding of the embodiments according to the present application, and constitute a part of the specification. They are used to illustrate the embodiments according to the present application, and explain the principles of the present application in conjunction with the text description. Apparently, the drawings in the following description merely represent some embodiments of the present disclosure, and for those having ordinary skill in the art, other drawings may also be obtained based on these drawings without investing creative. In the drawings:

FIG. 1 is a schematic diagram of a first flexible color electronic paper display panel according to an embodiment of the present application.

FIG. 2 is a schematic diagram of a second flexible color electronic paper display panel according to an embodiment of the present application.

FIG. 3 is a schematic diagram of an array substrate in an unbent state according to a first embodiment of the present application.

FIG. 4 is a schematic diagram of an array substrate in a bent state according to the first embodiment of the present application.

FIG. 5 is a schematic diagram of a related flexible color electronic paper display panel.

FIG. 6 is a schematic diagram of a bent state of a related flexible color electronic paper display panel.

FIG. 7 is a plan schematic diagram of an array substrate according to the first embodiment of the present application.

FIG. 8 is a schematic diagram of a first type of array substrate including a first region and a second region according to the first embodiment of the present application.

FIG. 9 is a schematic diagram of pixel electrodes in the first region of the first type of array substrate in a bent state according to the first embodiment of the present application.

FIG. 10 is a schematic diagram of pixel electrodes in the second region of the first type of array substrate in the bent state according to the first embodiment of the present application.

FIG. 11 is a schematic diagram of pixel electrodes in a first region of a second type of array substrate according to the first embodiment of the present application.

FIG. 12 is a schematic diagram of pixel electrodes in a second region of the second type of array substrate according to the first embodiment of the present application.

FIG. 13 is a schematic diagram of pixel electrodes of a third type of array substrate according to the first embodiment of the present application.

FIG. 14 is a schematic diagram of a control method for a flexible color electronic paper display panel according to an embodiment of the present application.

FIG. 15 is a schematic diagram of an array substrate according to the second embodiment of the present application.

In the drawings: 10, flexible color electronic paper display panel; 100, color filter substrate; 110, color filter base; 120, color filter layer; 121, color filter; 200, common electrode; 210, protective layer; 300, electrophoretic reflective layer; 310, microcapsule; 311, electrophoretic particle; 312, colloidal suspension; 313, electrophoretic ink; 314, base layer; 315, micro-cup; 316, barrier wall; 400, array substrate; 410, center line; 421, first direction; 422, second direction; 430, display area; 431, first region; 432, middle region; 433, second region; 440, non-display area; 450, pixel element region; 451, first sub-pixel element region; 452, second sub-pixel element region; 610, array base; 620, active switching layer; 621, first active switch; 622, second active switch; 631, first data line; 632, second data line; 640, scan line; 641, first scan line; 642, second scan line; 700, pixel electrode layer; 710, pixel electrode; 711, first sub-pixel electrode; 712, second sub-pixel electrode.

### DETAILED DESCRIPTION OF EMBODIMENTS

It should be understood that the terms used herein, the specific structures and functional details disclosed therein are merely representative for describing some specific embodiments, but the present application can be implemented in many alternative forms and should not be construed as being limited to only these embodiments described herein.

As used herein, terms “first”, “second”, or the like are merely used for illustrative purposes, and shall not be construed as indicating relative importance or implicitly indicating the number of technical features specified. Thus, unless otherwise specified, the features defined by “first” and “second” may explicitly or implicitly include one or more of such features. Terms “multiple”, “a plurality of”, and the like mean two or more. Terms “comprise”, “comprising”, “includes”, “including”, and any variations thereof are intended to be non-exclusive, and one or more other features, integers, steps, operations, units, components, and/or combinations thereof may be present or be added.

In addition, terms “center” “lateral”, “up”, “down”, “left”, “right”, “vertical”, and “horizontal”, “top”, “bottom”, “inside”, or the like are used to indicate orientational or relative positional relationships based on those illustrated in the drawings. They are merely intended for simplifying the description of the present disclosure, rather than indicating or implying that the device or element referred to must have a particular orientation or be constructed and operate in a particular orientation. Therefore, these terms are not to be construed as restricting the present disclosure.

In addition, unless otherwise clearly specified and defined, the terms “installed on”, “disposed on”, “arranged on”, and “connected to” should be understood in a broad sense. For example, it may be a fixed connection, a detachable connection, or an integral connection; it may be a mechanical connection or an electrical connection; it may be a direct connection or an indirect connection through an intermediate medium, or it may be internal communication between two elements. For those of ordinary skill in the art, the specific meanings of the above terms as used in the present application can be understood depending on specific contexts.

The present application will be described in detail below with reference to the accompanying drawings and some optional embodiments.

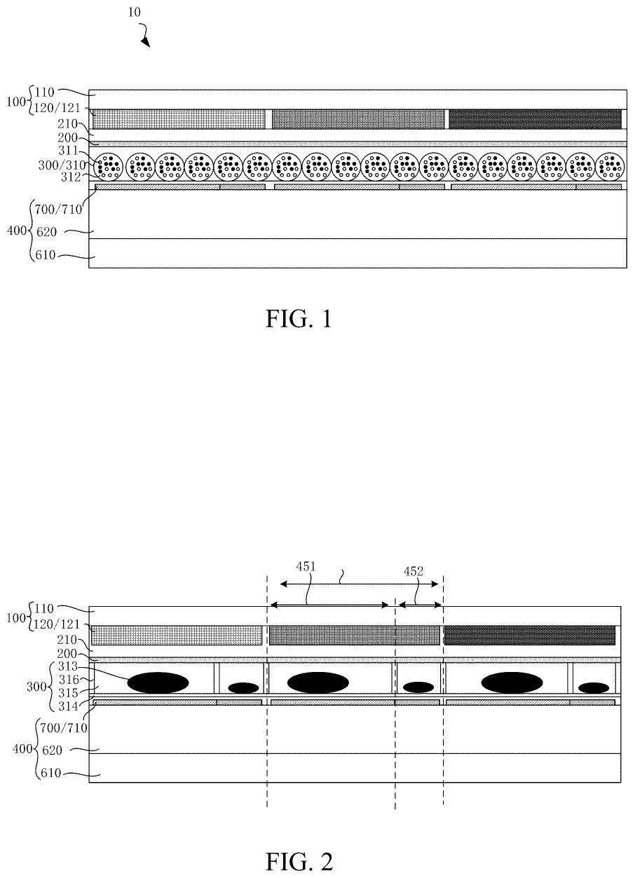

FIG. 1 is a schematic diagram of a first flexible color electronic paper display panel according to an embodiment of the present application. FIG. 2 is a schematic diagram of a second flexible color electronic paper display panel according to an embodiment of the present application. As shown in FIGS. 1 and 2, the present application discloses a flexible color electronic paper display panel 10. The flexible color electronic paper display panel 10 includes a color filter substrate 100, an electrophoretic reflective layer 300, and an array substrate 400. The electrophoretic reflective layer 300 is disposed between the color filter substrate 100 and the array substrate 400.

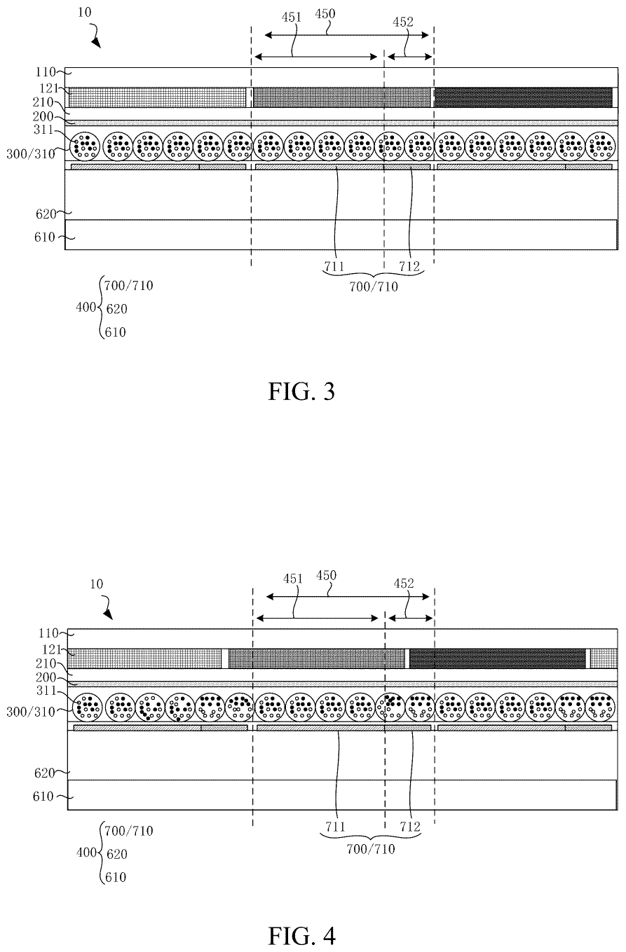

The color filter substrate 100 includes a color filter base 110 and a color filter layer 120. The color filter layer 120 is disposed on the color filter base 110. The color filter layer 120 includes multiple color filters 121, which are disposed in one-to-one correspondence with multiple pixel element regions 450 (as shown in FIG. 3). Furthermore, the orthographic projection of each color filter 121 on the color filter base 110 overlaps or coincides with the orthographic projection of the corresponding pixel electrode 710 on the color filter base 110. Exemplarily, the multiple color filters 121 include a red color filter 121, a green color filter 121, and a blue color filter 121.

The flexible color electronic paper display panel 10 further includes a common electrode 200 and a protective layer 210. The protective layer 210 is disposed on the side of the color filter layer 120 facing away from the color filter base 110. The common electrode 200 is disposed between the color filter substrate 100 and the electrophoretic reflective layer 300. The multiple pixel electrodes 710 on the array substrate 400 and the common electrode 200 drive the electrophoretic reflective layer 300 to absorb or reflect light.

The electrophoretic reflective layer 300 may be a microcapsule-type electrophoretic reflective layer 300 or a micro-cup-type electrophoretic reflective layer 300.

Referring to FIG. 1, in some embodiments where the electrophoretic reflective layer 300 is a microcapsule-type electrophoretic reflective layer 300, the electrophoretic reflective layer 300 includes a plurality of microcapsules 310. Each microcapsule 310 is filled with a plurality of electrophoretic particles 311 and a colloidal suspension 312. The plurality of electrophoretic particles 311 include multiple black electrophoretic particles 311 and multiple white electrophoretic particles 311. Each white electrophoretic particle 311 carries a negative charge, each black electrophoretic particle 311 carries a positive charge, and the colloidal suspension 312 exhibits electrical neutrality. When a negative voltage is applied to the corresponding pixel electrode 710, under the action of the electric field force, multiple black electrophoretic particles 311 move downward, and multiple white electrophoretic particles 311 move upward, thereby displaying a white state when viewed from above. When a positive voltage is applied to the corresponding pixel electrode 710, under the action of the electric field force, multiple black electrophoretic particles 311 move upward, and multiple white electrophoretic particles 311 move downward, thereby displaying a black state when viewed from above. Of course, multiple color electrophoretic particles 311 may also be filled inside the microcapsule 310, such as red electrophoretic particles 311, green electrophoretic particles 311, and blue electrophoretic particles 311.

Referring to FIG. 2, in some embodiments where the electrophoretic reflective layer 300 is a micro-cup-type electrophoretic reflective layer 300, the electrophoretic reflective layer 300 includes a base layer 314. Multiple micro-cups 315 are arranged on the base layer 314, and the multiple micro-cups 315 are disposed in one-to-one correspondence with the multiple pixel element regions 450. Each micro-cup 315 is filled with multiple electrophoretic particles 311 (as shown in FIG. 1) and a colloidal suspension 312 (as shown in FIG. 1). Alternatively, each micro-cup 315 is filled with an electrophoretic ink 313 and a colloidal suspension 312 (as shown in FIG. 1).

It should be noted that when the electrophoretic reflective layer 300 is a micro-cup-type electrophoretic reflective layer 300, a barrier wall 316 is arranged between the first sub-pixel element region 451 and the second sub-pixel element region 452. The barrier wall 316 divides each micro-cup 315 into two independent sub-micro-cups 315, thereby preventing interference to the first sub-pixel element region 451 when controlling the second sub-pixel element region 452.

The present application further discloses an array substrate 400, which can be used in the aforementioned flexible color electronic paper display panel 10 (as shown in FIG. 1). For the array substrate 400, the present application provides the following designs, which are specifically described in connection with several embodiments as follows.

### Embodiment 1

FIG. 3 is a schematic diagram of an array substrate according to a first embodiment of the present application in an unbent state. FIG. 4 is a schematic diagram of an array substrate according to the first embodiment of the present application in a bent state. As shown in FIGS. 3 to 4, the present application discloses an array substrate 400, which is used in a flexible color electronic paper display panel 10. The flexible color electronic paper display panel 10 includes an electrophoretic reflective layer 300. The array substrate 400 includes an array base 610, and an active switching layer 620 and a pixel electrode layer 700 that are sequentially disposed on the array base 610. The array substrate 400 further includes multiple pixel element regions 450.

The pixel electrode layer 700 includes multiple pixel electrodes 710, and the multiple pixel electrodes 710 are disposed in one-to-one correspondence with the multiple pixel element regions 450. Each pixel electrode 710 includes a first sub-pixel electrode 711 and a second sub-pixel electrode 712. Each pixel element region 450 includes a first sub-pixel element region 451 and a second sub-pixel element region 452. The first sub-pixel electrode 711 is located within the first sub-pixel element region 451. The second sub-pixel electrode 712 is located within the second sub-pixel element region 452. The second sub-pixel electrode 712 is disposed at a periphery of the first sub-pixel electrode 711.

When the flexible color electronic paper display panel 10 (as shown in FIG. 1) is in a bent state, the second sub-pixel electrode 712 can be used to control the corresponding electrophoretic reflective layer 300 in each second sub-pixel element region 452 to absorb light. When the flexible color electronic paper display panel 10 is in an unbent state, the voltage of each first sub-pixel electrode 711 is identical with that of the corresponding second sub-pixel electrode 712, and the electric fields within the corresponding first sub-pixel element region 451 and second sub-pixel element region 452 are identical.

Simply put, when the flexible color electronic paper display panel 10 is in a bent state, the second sub-pixel electrode 712 can be used to control the electrophoretic reflective layer 300 in the second sub-pixel element region 452 to be in a light-absorbing state. When the flexible color electronic paper display panel 10 is in an unbent state, the first sub-pixel electrode 711 and the second sub-pixel electrode 712 jointly participate in displaying the image.

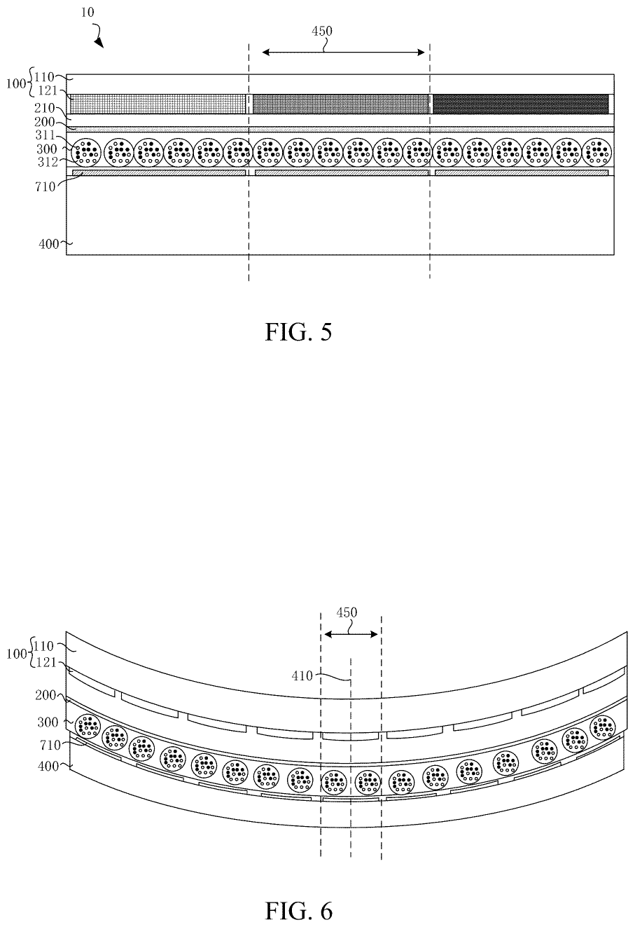

FIG. 5 is a schematic diagram of a related flexible color electronic paper display panel. FIG. 6 is a schematic diagram of the related flexible color electronic paper display panel in a bent state. Referring to FIGS. 5 and 6, taking the flexible color electronic paper display panel 10 bending upward at both sides and downward in the middle as an example, at this time, the color filter substrate 100 will pivot around the center point and generate sliding stresses towards the left and right on both sides relative to the array substrate 400, causing multiple color filters 121 on the color filter substrate 100 and corresponding multiple pixel electrodes 710 on the array substrate 400 to be misaligned at positions relatively far away from the center line 410 of the flexible color electronic paper display panel 10, causing the color filter 121 within one pixel element region 450 to shift into another pixel element region 450, thereby resulting in color shift and color mixing issues.

Compared to the related flexible color electronic paper display panels, this application divides each pixel electrode 710 into a first sub-pixel electrode 711 and a second sub-pixel electrode 712 (as shown in FIG. 3), where the second sub-pixel electrode 712 is disposed at a periphery of the first sub-pixel electrode 711. Thus, when the flexible color electronic paper display panel 10 is in a bent state, although each color filter 121 on the color filter substrate 100 shifts relative to the corresponding pixel electrode 710 on the array substrate 400, the shifted color filter 121 would fall onto the second sub-pixel electrode 712 of an adjacent pixel element region 450. At this time, the second sub-pixel electrode 712 can be used to control the electrophoretic reflective layer 300 in the second sub-pixel element region 452 (as shown in FIG. 3 or FIG. 4) to absorb light, thereby preventing color shift and color mixing issues in the flexible color electronic paper display panel 10.

Furthermore, when the flexible color electronic paper display panel 10 is in an unbent state, the first sub-pixel electrode 711 and the second sub-pixel electrode 712 have the same voltage, and the electric fields within the first sub-pixel element region 451 (as shown in FIG. 3 or FIG. 4) and the second sub-pixel element region 452 are identical. Simply put, when the flexible color electronic paper display panel 10 is not bent, the second sub-pixel electrode 712 and the first sub-pixel electrode 711 jointly participate in the display, thus preventing a reduction in brightness of the flexible color electronic paper display panel 10 when it is in the unbent state.

The width of the second sub-pixel electrode 712 is greater than or equal to the shifting amount of the color filter 121 when the flexible color electronic paper display panel 10 is in a bent state, and the area of the first sub-pixel electrode 711 is larger than that of the second sub-pixel electrode 712, which can prevent the problem of excessively low brightness of the flexible color electronic paper display panel 10 caused by controlling the electrophoretic reflective layer 300 within the second sub-pixel element region 452 to absorb light when the flexible color electronic paper display panel 10 is bent.

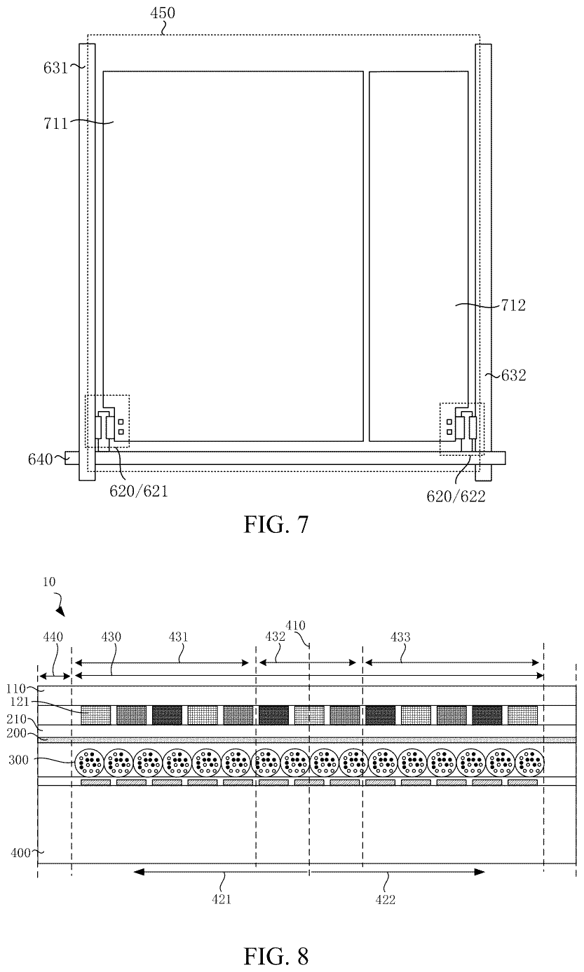

FIG. 7 is a plan schematic diagram of an array substrate according to the first embodiment of the present application. Referring to FIG. 7, in this embodiment, the first sub-pixel electrode 711 and the second sub-pixel electrode 712 in each pixel element region are controlled by a single scan line 640. Specifically, the active switching layer 620 includes a first active switch 621, a second active switch 622, a first data line 631, a second data line 632, and a scan line 640. The first active switch 621, the second active switch 622, the first data line 631, the second data line 632, and the scan line 640 are all disposed on the array base 610. The first data line 631 and the scan line 640 are arranged in a grid pattern to define each pixel element region 450 (as shown in FIG. 3 or FIG. 4).

The first active switch 621 connects the first data line 631 and the first sub-pixel electrode 711. The second active switch 622 connects the second data line 632 and the second sub-pixel electrode 712. The scan line 640 simultaneously controls the first active switch 621 and the second active switch 622 to be turned on.

The first active switch 621 and the second active switch 622 may each be a single-gate type active switch or a dual-gate type active switch.

In this embodiment, the scan line 640 simultaneously turns on the first active switch 621 and the second active switch 622. This allows both identical or different voltages to be applied to the first sub-pixel electrode 711 and the second sub-pixel electrode 712 at the same time, thereby reducing the number of metal wires in the array substrate 400, lowering the design complexity of the array substrate 400 (as shown in FIG. 1 or FIG. 2), and decreasing the degree of interference between different metal wires.

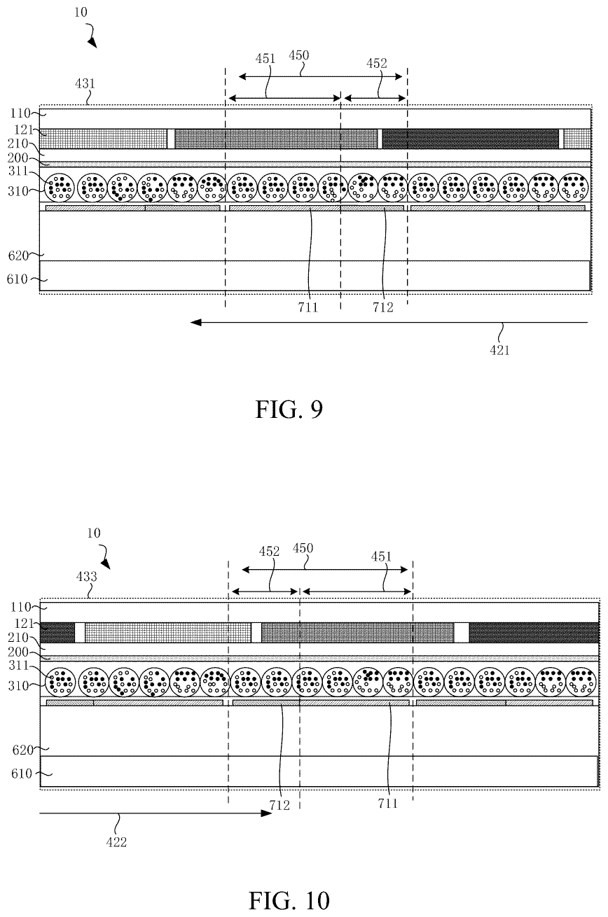

FIG. 8 is a schematic diagram of a first type of array substrate including a first region and a second region according to the first embodiment of the present application. FIG. 9 is a schematic diagram of pixel electrodes in the first region of the first type of array substrate in a bent state according to the first embodiment of the present application. FIG. 10 is a schematic diagram of pixel electrodes in the second region of the first type of array substrate in a bent state according to the first embodiment of the present application. As shown in FIGS. 8 to 10, when the flexible color electronic paper display panel 10 bends with both sides upward and the middle downward, the corresponding color filter 121 in each pixel element region 450 on the left side of the panel shifts leftward, and the corresponding color filter 121 in each pixel element region 450 on the right side of the panel shifts rightward. Therefore, the present application provides a targeted design for this type of flexible color electronic paper display panel 10 that bends with both sides upward and the center downward.

Specifically, the array substrate 400 includes a display area 430 and a non-display area 440, where the non-display area 440 surrounds the display area 430. The plurality of pixel element regions 450 are disposed within the display area 430. The display area 430 includes a first region 431 and a second region 433. The first region 431 and the second region 433 are respectively located on opposite sides of the center line 410.

In each pixel element region 450 in the first region 431, the second sub-pixel electrode 712 is located on the side of the first sub-pixel electrode 711 facing toward the second region 433. In each pixel element region 450 in the second region 433, the second sub-pixel electrode 712 is located on the side of the first sub-pixel electrode 711 facing toward the first region 431.

The center line 410 is defined as the position at the center when the two sides of the flexible color electronic paper display panel 10 bend toward the middle.

While addressing the issues of color shift and color mixing in the flexible color electronic paper display panel 10, it is not needed to arrange the second sub-pixel electrodes 712 on both sides of the first sub-pixel electrode 711, nor is it required to design connecting wires, thereby simplifying the structure of the array substrate 400.

Furthermore, the display area 430 further includes a middle region 432, which is located between the first region 431 and the second region 433. In each pixel element region 450 of the middle region 432, since the shifting amount of each color filter 121 in the middle region 432 is small, no second sub-pixel electrode 712 may be disposed in the middle region 432.

Of course, in consideration of the display uniformity of the entire flexible color electronic paper display panel 10, multiple second sub-pixel electrodes 712 may also be disposed in the middle region 432. Each of the second sub-pixel electrodes 712 may be located on the left side or the right side of the corresponding first sub-pixel electrode 711, or may even be simultaneously disposed on both the left and right sides of the first sub-pixel electrode 711.

The direction extending from the center line 410 toward the first region 431 is defined as a first direction 421, and the direction extending from the center line 410 toward the second region 433 is defined as a second direction 422.

Since the farther from the center line 410, the greater the shift of the color filter 121, in this application, the width of the corresponding second sub-pixel electrode 712 gradually increases along the first direction 421 in each pixel element region 450 of the first region 431, and the width of the corresponding second sub-pixel electrode 712 gradually increases along the second direction 422 in each pixel element region 450 of the second region 433.

This can avoid the problem where the shifting amount of the corresponding color filter 121 in each pixel element region 450 near the center line 410 is smaller than the shifting amount of the corresponding color filter 121 in each pixel element region 450 farther from the center line 410. If the maximum shifting amount of multiple color filters 121 is used as the width of the second sub-pixel electrode 712 near the center line 410, it will cause brightness loss in that pixel element region 450.

Furthermore, it can avoid the situation where the shifting amount of the corresponding color filter 121 in each pixel element region 450 farther from the center line 410 is greater than the shifting amount of the corresponding color filter 121 in each pixel element region 450 near the center line 410. If multiple second sub-pixel electrodes 712 with the same width as those near the center line 410 are used, it will cause the shifted color filter 121 to extend beyond the area of the second sub-pixel electrode 712, thereby failing to solve the color shift or color mixing problem.

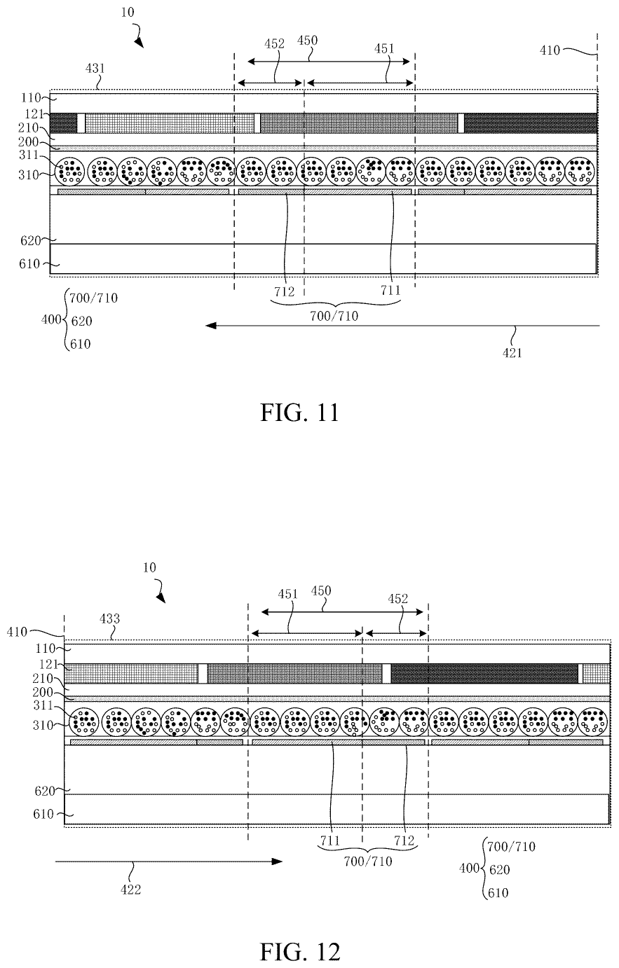

FIG. 11 is a schematic diagram of pixel electrodes in a first region of a second type of array substrate according to the first embodiment of the present application. FIG. 12 is a schematic diagram of pixel electrodes in a second region of the second type of array substrate according to the first embodiment of the present application. As shown in FIGS. 11 to 12, when the flexible color electronic paper display panel 10 bends downward on both sides and upward in the middle, the corresponding color filter 121 in each pixel element region 450 on the left side of the flexible color electronic paper display panel 10 would shift to the right, and the corresponding color filter 121 in the pixel element region 450 on the right side would shift to the left. Therefore, this application provides a targeted design for the flexible color electronic paper display panel 10 that bends downward on both sides and upward in the middle.

Specifically, the array substrate 400 includes a display area 430 and a non-display area 440 (as shown in FIG. 8), where the non-display area 440 surrounds the display area 430. The plurality of pixel element regions 450 are located within the display area 430. The display area 430 includes a first region 431 and a second region 433, which are respectively located on both sides of the center line 410.

In each pixel element region 450 within the first region 431, the corresponding second sub-pixel electrode 712 is located on the side of the corresponding first sub-pixel electrode 711 facing away from the second region 433. In each pixel element region 450 within the second region 433, the corresponding second sub-pixel electrode 712 is located on the side of the corresponding first sub-pixel electrode 711 facing away from the first region 431.

While solving the color shift and color mixing problems of the flexible color electronic paper display panel 10, it is not needed to arrange the second sub-pixel electrode 712 on both sides of each first sub-pixel electrode 711, nor is it required to design connecting wires, thereby simplifying the structure of the array substrate 400 (as shown in FIG. 8).

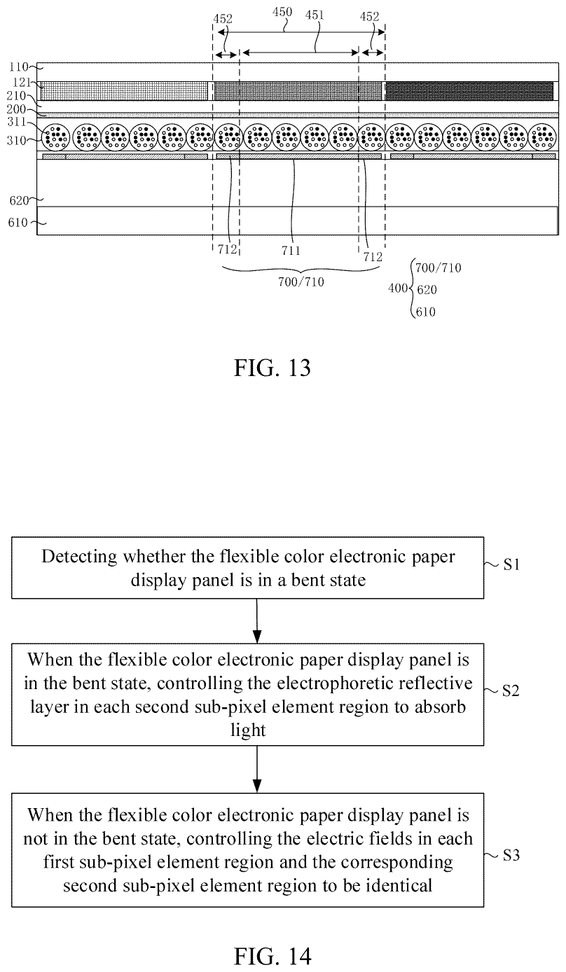

FIG. 13 is a schematic diagram of pixel electrodes of a third type of array substrate according to the first embodiment of the present application. As shown in FIG. 13, the array substrate 400 (as shown in FIG. 8) includes a display area 430 and a non-display area 440 (as shown in FIG. 8), where the non-display area 440 surrounds the display area 430. The plurality of pixel element regions 450 are located within the display area 430. The display area 430 includes a first region 431 and a second region 433, which are respectively located on both sides of the center line 410.

The number of second sub-pixel electrodes 712 in each pixel element region 450 includes two, and the two second sub-pixel electrodes 712 in each pixel element region 450 are electrically connected. In each pixel element region 450 in the first region 431, the two corresponding second sub-pixel electrodes 712 are respectively located on the sides of the corresponding first sub-pixel electrode 711 that face towards and away from the second region 433. In each pixel element region 450 in the second region 433, the two corresponding second sub-pixel electrodes 712 are respectively located on the sides of the corresponding first sub-pixel electrode 711 that are face towards and away from the first region 431.

Simply put, regardless of whether it is in each pixel element region 450 of the first region 431 or in each pixel element region 450 of the second region 433, the number of second sub-pixel electrodes 712 is two.

Exemplarily, in each pixel element region 450 of the first region 431, one second sub-pixel electrode 712 is located on the side of the corresponding first sub-pixel electrode 711 facing towards the second region 433, and the other second sub-pixel electrode 712 is located on the side of the corresponding first sub-pixel electrode 711 facing away from the second region 433. In this way, regardless of whether the flexible color electronic paper display panel 10 bends forward or backward, the second sub-pixel electrode 712 can cover the correspondingly shifted color filter 121, thereby avoiding the problems of color mixing and color shift.

The two second sub-pixel electrodes 712 are directly connected, which can be achieved through a via and a connecting wire, so there is no need to additionally provide another active switch and data line.

FIG. 14 is a schematic diagram of a control method for a flexible color electronic paper display panel according to an embodiment of the present application. As shown in FIG. 14, and with reference to FIGS. 1 to 13, the present application further discloses a control method for a flexible color electronic paper display panel 10, which is applied to the above-mentioned flexible color electronic paper display panels 10. The control method of the flexible color electronic paper display panel 10 includes the following operations:
S1: detecting whether the flexible color electronic paper display panel is in a bent state;
S2: when the flexible color electronic paper display panel is in the bent state, controlling the electrophoretic reflective layer in each second sub-pixel element region to absorb light; and
S3: when the flexible color electronic paper display panel is not in the bent state, controlling the electric fields in each first sub-pixel element region and the corresponding second sub-pixel element region to be identical.

Detecting whether the flexible color electronic paper display panel 10 is in a bent state can be achieved by arranging a touch electrode within the flexible color electronic paper display panel 10. When the flexible color electronic paper display panel 10 bends, the dielectric constant of the dielectric changes, which in turn causes a change in the capacitance value. The touch sensing capacitance value of the touch electrode changes accordingly, so by detecting the change in the touch sensing capacitance value, the bending state of the panel can be detected and determined.

Specifically, a first method, namely self-capacitance sensing, can be employed. In self-capacitance sensing, each touch electrode operates independently, and the bending state is determined by measuring the capacitance between the touch electrode and the power ground. When the touch screen bends, the capacitance value between the touch electrode in the bending region and the power ground changes. By detecting the change in this capacitance value, the bending degree and bending position can be determined.

The second method is mutual-capacitance sensing. Mutual-capacitance sensing works by using a combination of a transmitting electrode and a receiving electrode. When the touch screen bends, the mutual capacitance between the transmitting electrode and the receiving electrode in the bending region changes. By measuring the amount of charges received on the receiving electrode (which is proportional to the mutual capacitance), the bending state can be determined.

By dividing each pixel electrode 710 into a first sub-pixel electrode 711 and a second sub-pixel electrode 712, where the second sub-pixel electrode 712 is disposed at a periphery of the first sub-pixel electrode 711, when the flexible color electronic paper display panel 10 is in a bent state, although each of the multiple color filters 121 on the color filter substrate 100 shifts relative to the corresponding pixel electrode 710 on the array substrate 400, the shifted color filter 121 will fall onto the second sub-pixel electrode 712 of the adjacent pixel element region 450. At this time, the second sub-pixel electrode 712 controls the electrophoretic reflective layer 300 in the second sub-pixel element region 452 to absorb light, thereby avoiding color shift and color mixing problems in the flexible color electronic paper display panel 10.

Furthermore, when the flexible color electronic paper display panel 10 is in an unbent state, the first sub-pixel electrode 711 and the second sub-pixel electrode 712 have the same voltage, and the electric fields in the first sub-pixel element region 451 and the second sub-pixel element region 452 are identical. Simply put, when the flexible color electronic paper display panel 10 is not bent, the second sub-pixel electrode 712 participates in the display, thus preventing a reduction in brightness when the panel is unbent.

The operation of S2, namely when the flexible color electronic paper display panel is in a bent state, controlling the electrophoretic reflective layer within the second sub-pixel element region to absorb light, includes:
S21: when the flexible color electronic paper display panel is in the bent state, applying a positive voltage to the second sub-pixel electrode to control the electrophoretic reflective layer within the second sub-pixel element region to absorb light.

By applying a positive voltage to the second sub-pixel electrode 712, multiple black electrophoretic particles 311 in the electrophoretic reflective layer 300 within the first sub-pixel element region 451 would move upward, thereby achieving the purpose of the electrophoretic reflective layer 300 within the second sub-pixel element region 452 absorbing light.

Since in this embodiment the scan line 640 simultaneously controls the first active switch 621 and the second active switch 622, when a positive voltage is applied to the second sub-pixel electrode 712, the first active switch 621 may also be turned on. Therefore, it is needed to reapply the display voltage to the first sub-pixel electrode 711 while applying the positive voltage to the second sub-pixel electrode 712, as follows:
The operation of S21, namely when the flexible color electronic paper display panel is in a bent state, applying a positive voltage to the second sub-pixel electrode to control the electrophoretic reflective layer within the second sub-pixel element region to absorb light, includes:
S211: when the flexible color electronic paper display panel is in a bent state, applying a positive voltage to the second sub-pixel electrode while simultaneously applying the display voltage to the first sub-pixel electrode, so as to control the electrophoretic reflective layer within the second sub-pixel element region to absorb light.

Thus, when applying a positive voltage to the second sub-pixel electrode 712, leakage current from the first sub-pixel electrode 711 is prevented, thereby avoiding issues that would affect the display quality.

When the flexible color electronic paper display panel 10 is in a bent state, since the second sub-pixel electrode 712 controls the electrophoretic reflective layer 300 within the second pixel element region 450 to absorb light, the display brightness of the flexible color electronic paper display panel 10 decreases. Therefore, the present application further provides that while applying a positive voltage to the second sub-pixel electrode 712, a display voltage greater than or less than the initial display voltage is applied to the first sub-pixel electrode 711, specifically as follows.

When the initial display voltage of the first sub-pixel electrode 711 is a positive voltage, the display voltage is less than the initial display voltage. When the initial display voltage of the first sub-pixel electrode 711 is a negative voltage, the display voltage is greater than the initial display voltage.

Exemplarily, when the flexible color electronic paper display panel 10 is not in a bent state, the voltages of the first sub-pixel electrode 711 and the second sub-pixel electrode 712 within the current pixel element region 450 are both the initial display voltage, for example, +10V.

When the flexible color electronic paper display panel 10 is in a bent state, a voltage of +15V is applied to the second sub-pixel electrode within the current pixel element region 450, causing the electrophoretic reflective layer 300 in the second sub-pixel element region 452 to absorb light and display black. Meanwhile, a display voltage, for example +8V, is applied to the first sub-pixel electrode 711 to increase the brightness of the first sub-pixel element region 451, thereby balancing the brightness and contrast reduction of the flexible color electronic paper display panel 10 caused by the darkening of the second sub-pixel element region 452.

Exemplarily, when the flexible color electronic paper display panel 10 is not in a bent state, the voltages of the first sub-pixel electrode 711 and the second sub-pixel electrode within the current pixel element region 450 are both the initial display voltage, for example, −10V.

When the flexible color electronic paper display panel 10 is in a bent state, a voltage of +15V is applied to the second sub-pixel electrode 712 within the current pixel element region 450, causing the electrophoretic reflective layer 300 in the second sub-pixel element region 452 to absorb light and display black. A display voltage, for example, −15V, is applied to the first sub-pixel electrode 711 to increase the brightness of the first sub-pixel element region 451, thereby balancing the brightness and contrast reduction of the flexible color electronic paper display panel 10 caused by the darkening of the second sub-pixel element region 452.

Furthermore, the farther away from the center line 410, the greater the shift of the color filter 121. Therefore, in each pixel element region 450 of the first region 431, along the first direction 421, the width of the second sub-pixel electrode 712 gradually increases. In each pixel element region 450 of the second region 433, along the second direction 422, the width of the second sub-pixel electrode 712 gradually increases.

Therefore, when compensating the first sub-pixel electrode 711, if the initial display voltage of the first sub-pixel electrode 711 is a positive voltage, the display voltage is less than the initial display voltage, and along the first direction 421, the difference between the display voltage and the initial display voltage gradually increases.

When the initial display voltage of the first sub-pixel electrode 711 is a negative voltage, the display voltage is greater than the initial display voltage, and along the first direction 421, the difference between the display voltage and the initial display voltage gradually increases.

Thus, it avoids the problem where the first sub-pixel electrode 711 in any pixel element region 450 uses the same compensation voltage difference, which causes the flexible color electronic paper display panel 10 to become darker closer to the edges, thereby improving the uniformity of the flexible color electronic paper display panel 10.

### Embodiment 2

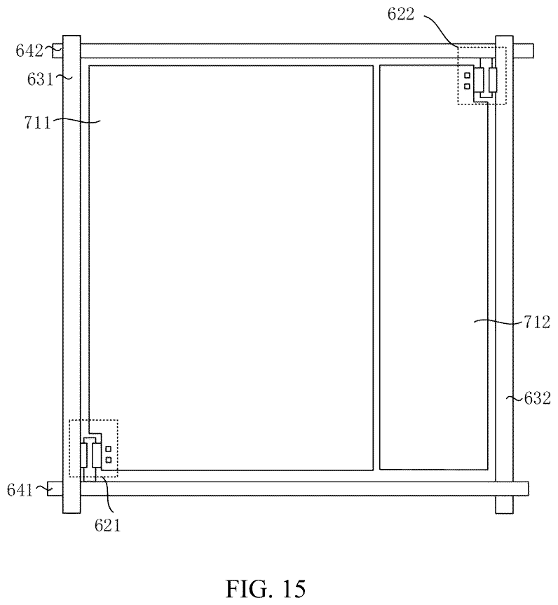

FIG. 15 is a schematic diagram of an array substrate according to a second embodiment of the present application. As shown in FIG. 15, unlike the first embodiment, this embodiment is provided with two scan lines 640, namely a first scan line 641 and a second scan line 642 The first scan line 641 controls the first active switch 621 to be turned on. The second scan line 642 controls the second active switch 622 to be turned on, specifically as follows.

The active switching layer 620 includes a first active switch 621, a second active switch 622, a first data line 631, a second data line 632, a first scan line 641, and a second scan line 642. The first active switch 621, the second active switch 622, the first data line 631, the second data line 632, the first scan line 641, and the second scan line 642 are all disposed on the array base 610. The first data line 631 and the first scan line 641 are arranged in a grid pattern to define each of the pixel element regions 450 (as shown in FIG. 3).

The first active switch 621 connects the first data line 631 and the first sub-pixel electrode 711. The second active switch 622 connects the second data line 632 and the second sub-pixel electrode 712. The first scan line 641 controls the first active switch 621 to be turned on. The second scan line 642 controls the second active switch 622 to be turned on.

Compared with the scheme of the first embodiment, this embodiment sets two scan lines 640, enabling the second sub-pixel electrode 712 to be controlled independently. When the flexible color electronic paper display panel 10 is in a bent state, the second sub-pixel electrode 712 can be independently supplied with a positive voltage, without needing to input a display voltage to the first sub-pixel electrode 711, thereby achieving control of the electrophoretic reflective layer 300 in the second sub-pixel element region 452 (as shown in FIG. 3) to absorb light without affecting the display of the image.

It should be noted that the limitations of the various steps or operations involved in this solution are not to be interpreted to limit the order of the steps or operations, under the premise of not affecting the implementation of the specific solution. The steps or operations written earlier can be executed first, or later, or even at the same time as the steps or operations written later. As long as this solution can be implemented, it should be regarded as falling within the scope of protection of this application.

It should be noted that the inventive concept of the present application can be formed into many embodiments, but the length of the application document is limited and so these embodiments cannot be enumerated one by one. Therefore, should no conflict be present, the various embodiments or technical features described above can be arbitrarily combined to form new embodiments. After the various embodiments or technical features are combined, the original technical effects may be enhanced.

The foregoing is a further detailed description of the present application with reference to some specific optional implementations, but it cannot be determined that the specific implementation of the present application is limited to these implementations. For those having ordinary skill in the technical field to which the present application pertains, several deductions or substitutions may be made without departing from the concept of the present application, and all these deductions or substitutions should be regarded as falling within the scope of protection of the present application.

What is claimed is:

1. An array substrate for use in a flexible color electronic paper display panel, wherein the flexible color electronic paper display panel comprises an electrophoretic reflective layer; wherein the array substrate comprises an array base, and an active switching layer and a pixel electrode layer that are sequentially disposed on the array base, and wherein the array substrate further comprises a plurality of pixel element regions;
wherein the pixel electrode layer comprises a plurality of pixel electrodes, the plurality of pixel electrodes being disposed in one-to-one correspondence with the plurality of pixel element regions; wherein each of the plurality of pixel electrodes comprises a first sub-pixel electrode and a second sub-pixel electrode, and each of the plurality of pixel element regions comprises a first sub-pixel element region and a second sub-pixel element region; wherein the first sub-pixel electrode is disposed within the first sub-pixel element region, the second sub-pixel electrode is disposed within the second sub-pixel element region, and wherein the second sub-pixel electrode is disposed at a periphery of the first sub-pixel electrode;
wherein in response to the flexible color electronic paper display panel being in a bent state, each second sub-pixel electrode is configured to control the electrophoretic reflective layer within a corresponding second sub-pixel element region to absorb light; and in response to the flexible color electronic paper display panel being in an unbent state, each first sub-pixel electrode and a corresponding second sub-pixel electrode are operative to have an identical voltage, and an electric field within a corresponding first sub-pixel element region is identical with an electric field within a corresponding second sub-pixel element region.

2. The array substrate as recited in claim 1, wherein the array substrate comprises a display area and a non-display area surrounding the display area; wherein the plurality of pixel element regions are disposed within the display area; wherein the display area comprises a first region and a second region, the first region and the second region being respectively located on opposite sides of a center line;
wherein in each pixel element region in the first region, a corresponding second sub-pixel electrode is located on a side of a corresponding first sub-pixel electrode facing toward the second region; and wherein in each pixel element region in the second region, a corresponding second sub-pixel electrode is located on a side of a corresponding first sub-pixel electrode facing toward the first region.

3. The array substrate as recited in claim 1, wherein the array substrate comprises a display area and a non-display area surrounding the display area; wherein the plurality of pixel element regions are located within the display area; wherein the display area comprises a first region and a second region, the first region and the second region being respectively located on opposite sides of a center line;
wherein in each pixel element region in the first region, a corresponding second sub-pixel electrode is located on a side of a corresponding first sub-pixel electrode facing away from the second region; and wherein in each pixel element region in the second region, a corresponding second sub-pixel electrode is located on a side of a corresponding first sub-pixel electrode facing away from the first region.

4. The array substrate as recited in claim 1, wherein the array substrate comprises a display area and a non-display area surrounding the display area; wherein the plurality of pixel element regions are located within the display area; wherein the display area comprises a first region and a second region, the first region and the second region being respectively located on opposite sides of a center line;
wherein each pixel element region comprises two second sub-pixel electrodes that are electrically connected; wherein in each pixel element region in the first region, one of the two corresponding second sub-pixel electrodes is disposed on a side of a corresponding first sub-pixel electrode facing toward the second region, and another of the two corresponding second sub-pixel electrodes is disposed on a side of the corresponding first sub-pixel electrode facing away from the second region; and wherein in each pixel element region in the second region, one of the two corresponding second sub-pixel electrodes is disposed on a side of a corresponding first sub-pixel electrode facing toward the first region, and another of the two corresponding second sub-pixel electrodes is disposed on a side of the corresponding first sub-pixel electrode facing away from the first region.

5. The array substrate as recited in claim 2, wherein a direction extending from the center line toward the first region is defined as a first direction, and a direction extending from the center line toward the second region is defined as a second direction;
wherein in each pixel element region in the first region, a width of the second sub-pixel electrode gradually increases along the first direction, and wherein in each pixel element region in the second region, a width of the second sub-pixel electrode gradually increases along the second direction.

6. The array substrate as recited in claim 1, wherein the active switching layer comprises a first active switch, a second active switch, a first data line, a second data line, and a scan line; wherein the first active switch, the second active switch, the first data line, the second data line, and the scan line are all disposed on the array base, wherein the first data line and the scan line are arranged in a grid pattern to define each of the plurality of pixel element regions;
wherein the first active switch connects the first data line to the first sub-pixel electrode, the second active switch connects the second data line to the second sub-pixel electrode, and wherein the scan line is configured to simultaneously control the first active switch and the second active switch to be turned on.

7. The array substrate as recited in claim 1, wherein the active switching layer comprises a first active switch, a second active switch, a first data line, a second data line, a first scan line, and a second scan line; wherein the first active switch, the second active switch, the first data line, the second data line, the first scan line, and the second scan line are all disposed on the array base; wherein the first data line and the first scan line are arranged in a grid pattern to define each of the plurality of pixel element regions;
wherein the first active switch connects the first data line to the first sub-pixel electrode, the second active switch connects the second data line to the second sub-pixel electrode, wherein the first scan line is configured to control the first active switch to be turned on, and wherein the second scan line is configured to control the second active switch to be turned on.

8. The array substrate as recited in claim 1, wherein an area of each first sub-pixel electrode is greater than an area of a corresponding second sub-pixel electrode.

9. The array substrate as recited in claim 3, wherein the display area further comprises a middle region disposed between the first region and the second region, and wherein no second sub-pixel electrode is disposed in each pixel element region within the middle region.

10. The array substrate as recited in claim 4, wherein the display area further comprises a middle region disposed between the first region and the second region, and wherein no second sub-pixel electrode is disposed in each pixel element region within the middle region.

11. A flexible color electronic paper display panel, comprising a color filter substrate, an electrophoretic reflective layer, and an array substrate; wherein the electrophoretic reflective layer is disposed between the color filter substrate and the array substrate;
wherein the array substrate comprises an array base, and an active switching layer and a pixel electrode layer that are sequentially disposed on the array base, and wherein the array substrate further comprises a plurality of pixel element regions;
wherein the pixel electrode layer comprises a plurality of pixel electrodes, the plurality of pixel electrodes being disposed in one-to-one correspondence with the plurality of pixel element regions, each pixel electrode comprising a first sub-pixel electrode and a second sub-pixel electrode, each pixel element region comprising a first sub-pixel element region and a second sub-pixel element region, wherein the first sub-pixel electrode is disposed within the first sub-pixel element region, the second sub-pixel electrode is disposed within the second sub-pixel element region, and wherein the second sub-pixel electrode is disposed at a periphery of the first sub-pixel electrode;
wherein in response to the flexible color electronic paper display panel being in a bent state, each second sub-pixel electrode is configured to control the electrophoretic reflective layer within a corresponding second sub-pixel element region to absorb light; in response to the flexible color electronic paper display panel being in an unbent state, each first sub-pixel electrode and a corresponding second sub-pixel electrode are operative to have an identical voltage, and an electric field within a corresponding first sub-pixel element region is identical with an electric field within a corresponding second sub-pixel element region.

12. The flexible color electronic paper display panel as recited in claim 11, wherein the color filter substrate comprises a color filter base and a color filter layer disposed on the color filter base, the color filter layer comprising a plurality of color filters, the plurality of color filters disposed in one-to-one correspondence with the plurality of pixel element regions;
wherein an orthographic projection of each color filter on the color filter base overlaps or coincides with an orthographic projection of a corresponding pixel electrode on the color filter base.

13. The flexible color electronic paper display panel as recited in claim 11, further comprising a common electrode and a protective layer, wherein the protective layer is disposed on a side of the color filter layer facing away from the color filter base, and wherein the common electrode is disposed between the color filter substrate and the electrophoretic reflective layer.

14. The flexible color electronic paper display panel as recited in claim 11, wherein the electrophoretic reflective layer comprises a plurality of microcapsules, each microcapsule being filled with a plurality of electrophoretic particles and a colloidal suspension;
wherein the plurality of electrophoretic particles comprising a plurality of black electrophoretic particles and a plurality of white electrophoretic particles, each white electrophoretic particle carrying a negative charge, each black electrophoretic particle carrying a positive charge, and the colloidal suspension being electrically neutral.

15. The flexible color electronic paper display panel as recited in claim 11, wherein the electrophoretic reflective layer comprises a base layer, wherein there are disposed a plurality of micro-cups on the base layer, wherein the plurality of micro-cups are disposed in one-to-one correspondence with the plurality of pixel element regions, and wherein each micro-cup is filled with an electrophoretic ink and a colloidal suspension.

16. The flexible color electronic paper display panel as recited in claim 11, wherein the electrophoretic reflective layer comprises a base layer, wherein there are disposed a plurality of micro-cups on the base layer, wherein the plurality of micro-cups are disposed in one-to-one correspondence with the plurality of pixel element regions, and wherein each micro-cup is filled with a plurality of electrophoretic particles and a colloidal suspension.

17. A control method for a flexible color electronic paper display panel, wherein the flexible color electronic paper display panel comprises a color filter substrate, an electrophoretic reflective layer, and an array substrate, the electrophoretic reflective layer being disposed between the color filter substrate and the array substrate; wherein the array substrate comprises an array base, and an active switching layer and a pixel electrode layer that are sequentially disposed on the array base, and wherein the array substrate further comprises a plurality of pixel element regions; wherein the pixel electrode layer comprises a plurality of pixel electrodes, the plurality of pixel electrodes being disposed in one-to-one correspondence with the plurality of pixel element regions, each pixel electrode comprising a first sub-pixel electrode and a second sub-pixel electrode, each pixel element region comprising a first sub-pixel element region and a second sub-pixel element region, wherein the first sub-pixel electrode is disposed within the first sub-pixel element region, the second sub-pixel electrode is disposed within the second sub-pixel element region, and wherein the second sub-pixel electrode is disposed at a periphery of the first sub-pixel electrode;
wherein the control method comprises:
detecting whether the flexible color electronic paper display panel is in a bent state;
in response to detecting that the flexible color electronic paper display panel is in the bent state, controlling the electrophoretic reflective layer within each second sub-pixel element region to absorb light; and
in response to detecting that the flexible color electronic paper display panel is not in the bent state, controlling an electric field within each first sub-pixel element region and an electric field within a corresponding second sub-pixel element region to be identical.

18. The control method as recited in claim 17, wherein the operation of controlling the electrophoretic reflective layer within each second sub-pixel element region to absorb light in response to detecting that the flexible color electronic paper display panel is in the bent state comprises:
in response to detecting that the flexible color electronic paper display panel is in the bent state, applying a positive voltage to each second sub-pixel electrode, thereby controlling the electrophoretic reflective layer within the corresponding second sub-pixel element region to absorb light.

19. The control method as recited in claim 18, wherein the operation of applying a positive voltage to each second sub-pixel electrode to control the electrophoretic reflective layer within the corresponding second sub-pixel element region to absorb light in response to detecting that the flexible color electronic paper display panel is in the bent state comprises:
in response to detecting that the flexible color electronic paper display panel is in the bent state, applying a positive voltage to each second sub-pixel electrode and simultaneously applying a display voltage to a corresponding first sub-pixel electrode, thereby controlling the electrophoretic reflective layer within the second sub-pixel element region to absorb light.
